(19) United States
(12) Patent Application Publication
(10) Pub. No.: US 2019/0328132 A1
(43) Pub. Date: Oct. 31, 2019

(54) SUPPORTING BRACKET FOR MOBILE TERMINAL

(71) Applicant: Futurepath Technology (Shenzhen) Co., Ltd., Shenzhen City (CN)

(72) Inventors: JUN XIAO, Shenzhen City (CN); XIAOBO WANG, Shenzhen City (CN); HAIZHEN LI, Shenzhen City (CN); JIANMING LU, Shenzhen City (CN); MINGSHUI RUAN, Shenzhen City (CN); WEICHAO LI, Shenzhen City (CN); LONG LI, Shenzhen City (CN)

(21) Appl. No.: 16/006,820

(22) Filed: Jun. 12, 2018

(30) Foreign Application Priority Data
Apr. 26, 2018 (CN) 201810382231.1

(51) Int. Cl. A47B 23/06; F16B 1/00; F16M 11/20

(52) U.S. Cl. CPC A47B 23/06; F16B 1/00; H05K 7/20136; F16B 2001/0035; F16M 11/2021

(57) ABSTRACT

A supporting bracket for supporting a mobile terminal on a platform includes a first bracket body provided with a bearing surface for supporting the mobile terminal and a supporting surface located below the bearing surface and configured for siting on the platform in order to support the bearing surface and changing an angle formed between the platform with the supporting bracket placed thereon and the mobile terminal leaned on the bearing surface. The supporting surface is a curved surface, and the bearing surface is connected with opposite ends of the supporting surface. Therefore, the supporting bracket is simple in structure, convenient to carry and easy to adjust the angle formed between the platform and the mobile terminal leaned on the bearing surface, and easy to be widely used.

### CROSS REFERENCE TO RELATED APPLICATIONS

This non-provisional patent application claims priority under 35 U.S.C. § 119(a) from Patent Application No. 201810382231.1 filed in The People's Republic of China on Apr. 26, 2018. The application is incorporated herein by reference.

### TECHNICAL FIELD

The present invention relates to the field of supporting structures, and in particular to a supporting bracket for mobile terminals.

### BACKGROUND

At present, with the advent of the information age, mobile terminal devices have become almost an important part of work and life for people, especially young and middle-aged people. Understandably, improper use of the mobile terminal devices often causes tension and strain on the muscles around the cervical spine. Therefore, it is particularly important to provide a supporting bracket for mobile terminal devices in order to reduce muscle tension and strain. However, the current supporting bracket for mobile terminal devices has limitations of being complicated to adjust the angle of the bracket and not convenient for carrying, which is not conductive to popularization and use.

### SUMMARY

Thus, there is a desire for an improved supporting bracket for mobile terminals so as to solve the above-mentioned problems.

The present embodiment provides a supporting bracket for supporting a mobile terminal on a platform. The supporting bracket comprises a first bracket body provided with a bearing surface for supporting the mobile terminal and a supporting surface located below the bearing surface and configured for siting on the platform in order to support the bearing surface and changing an angle formed between the platform with the supporting bracket placed thereon and the mobile terminal leaned on the bearing surface. The supporting surface is a curved surface, and the bearing surface is connected with opposite ends of the supporting surface.

Preferably, the first bracket body is provided with a holding cavity formed between the supporting surface and the bearing surface, the supporting bracket further includes a second bracket body comprising a curved plate and two end plates respectively disposed on opposite ends of the curved plate, and the curved plate is slidably installed in the holding cavity and at least one of the two end plates extends outside the holding cavity.

Preferably, the supporting bracket comprises a pair of the first bracket bodies and a pair of the second bracket bodies, each of the first bracket bodies has a connecting end and a free end opposite to the connecting end, the connecting ends are connected to each other, and inner ends of the second bracket bodies are respectively inserted into the free ends of the first bracket bodies.

Preferably, each of the connecting ends of the first bracket bodies is provided with a baffle, and the supporting surface, the bearing surface and the baffle are connected to one another to form the holding cavity, the baffles of the pair of the first bracket bodies are respectively provided with a first magnetic member and a second magnetic member attractive to the first magnetic member, wherein at least one of the first magnetic member and the second magnetic member is made of permanent magnet; the first bracket bodies are connected to each other by a magnetic attractive force formed between the first magnetic member and the second magnetic member; outer ends of the second bracket bodies respectively extend outside the first bracket bodies.

Preferably, the supporting bracket further comprises a third bracket body which is hollow, opposite ends of the third body are respectively disposed in the pair of the first bracket bodies, and the inner ends of the pair of the second bracket bodies are slidably disposed in the third body respectively.

Preferably, the second bracket body is provided with a limiting portion for limiting the insertion depth of the second bracket body inserting into the third bracket body, and the third bracket body is mounted between the two limiting portions.

Preferably, the bearing surface is provided with an anti-skid mat.

Preferably, the bearing surface is further provided with a third magnetic member and a fourth magnetic member attractive to the third magnetic member, wherein at least one of the third magnetic member and the fourth magnetic member is made of permanent magnet, and the third magnetic member and the fourth magnetic member are both located between the bearing surface and the anti-skid mat.

Preferably, the supporting bracket further includes two insertion members, each of the end plates of the second bracket body is provided with a curved groove, and the two insertion members are respectively inserted into the two curved grooves.

Preferably, the insertion member is provided with containg grooves.

Preferably, a plurality of arc-shaped ribs is arranged at the bottom of the supporting surface.

Preferably, the arc-shaped ribs are arranged along a length direction of the supporting surface and each rib extend along a width direction of the supporting surface.

Preferably, the bearing surface are provided with through holes.

Preferably, the through holes are arranged in a web shape.

Preferably, each of the two second bracket bodies is installed with a heat-dissipated device.

Preferably, the heat-dissipated device is a fan.

The present embodiment provides a supporting bracket for supporting a mobile terminal on a platform, comprising a first bracket body provided with a bearing surface for supporting the mobile terminal and a supporting surface located below the bearing surface and configured for siting on the platform, and a second bracket body comprising two end plates and a receiving space formed between the two end plates. A holding cavity is formed between the supporting surface and the bearing surface of the first bracket body, and the second bracket body is slidably mounted in the holding cavity of the first bracket body with at least one of the two end plates extending outside the holding cavity to expose the receiving space from the first bracket body.

Preferably, the supporting bracket comprises a pair of the first bracket bodies and a pair of the second bracket bodies, each of the first bracket bodies has a connecting end and a free end opposite to the connecting end, the connecting ends are connected to each other, and inner ends of the second bracket bodies are respectively inserted into the free ends of the first bracket bodies.

Preferably, the connecting ends of the pair of the first bracket bodies are respectively provided with a first magnetic member and a second magnetic member attractive to the first magnetic member.

Compared with the prior art, the present invention has the beneficial effects that:

According to the supporting bracket provided by an embodiment of the present invention, the first bracket body is provided with a bearing surface for supporting the mobile teminal and a supporting surface located below the bearing surface for supporting and changing the angle of the mobile terminal on the bearing surface, the supporting surface is a curved surface. The relative angle between the platform placing the supporting bracket and the mobile terminal located on the bearing surface can be changed by moving the first bracket body and/or roll the bearing surface. Therefore, the supporting bracket is simple in structure, convenient to carry and easy to adjust the angle formed between the platform and the mobile terminal leaned on the bearing surface, and easy to be widely used.

### BRIEF DESCRIPTION OF THE DRAWINGS

FIG. 1 is a schematic structural view of a supporting bracket for a mobile terminal according to the first embodiment and the second embodiment of the present disclosure;

FIG. 2 is an exploded view of the supporting bracket for a mobile terminal in the first embodiment of FIG. 1;

FIG. 3 is an A-A cross-sectional view of the first embodiment of FIG. 1;

FIG. 4 is a schematic structural view of the second bracket body in the first embodiment of FIG. 1;

FIG. 5 is a schematic structural view of the first bracket body in the first embodiment of FIG. 1;

FIG. 6 is a schematic strutural view of the insertion member of FIG. 1;

FIG. 7 is an exploded view of the supporting bracket for a mobile terminal in the second embodiment of FIG. 1;

FIG. 8 is an A-A cross-sectional view of the second embodiment of FIG. 1;

FIG. 9 is a schematic structural view of the second bracket body in the second embodiment of FIG. 1;

FIG. 10 is a schematic structural view of the first bracket body in the second embodiment of FIG. 1.

The figure: 10 (10′), first bracket body; 11 (11′), bearing surface; 111 (111′), through holes; 12 (12′) supporting surface; 121 (121′), arc-shaped protrusions; 13 (13′) anti-skid; 14 (14′), baffle; 15, first magnetic member; 16, second magnetic member; 17, third magnetic member; 18, fourth magnetic member; 20 (20′), second bracket body; 21 (21′), curved plate; 22 (22′), side plate; 23, limiting portion; 24 (24′), curved groove; 30, third bracket body; 40, insertion member; 41, containg groove; 50 (50′), heat-dissipated device.

### DETAILED DESCRIPTION OF THE PREFERRED EMBODIMENTS

Below, embodiments of the present invention will be described in greater detail with reference to the drawings. It should be noted that the figures are illustrative rather than limiting. The figures are not drawn to scale, do not illustrate every aspect of the described embodiments, and do not limit the scope of the present disclosure.

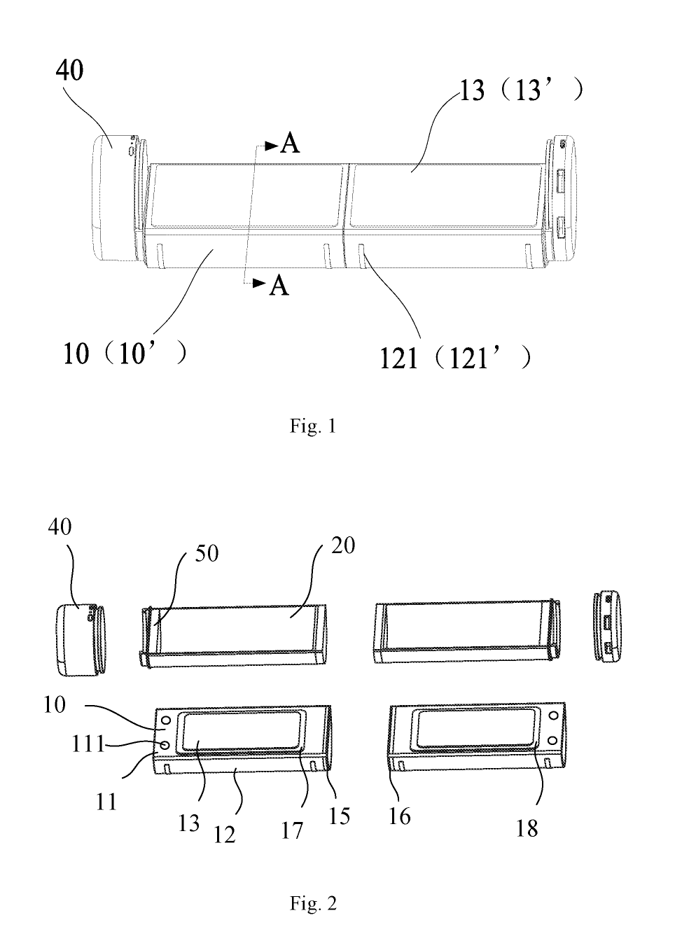

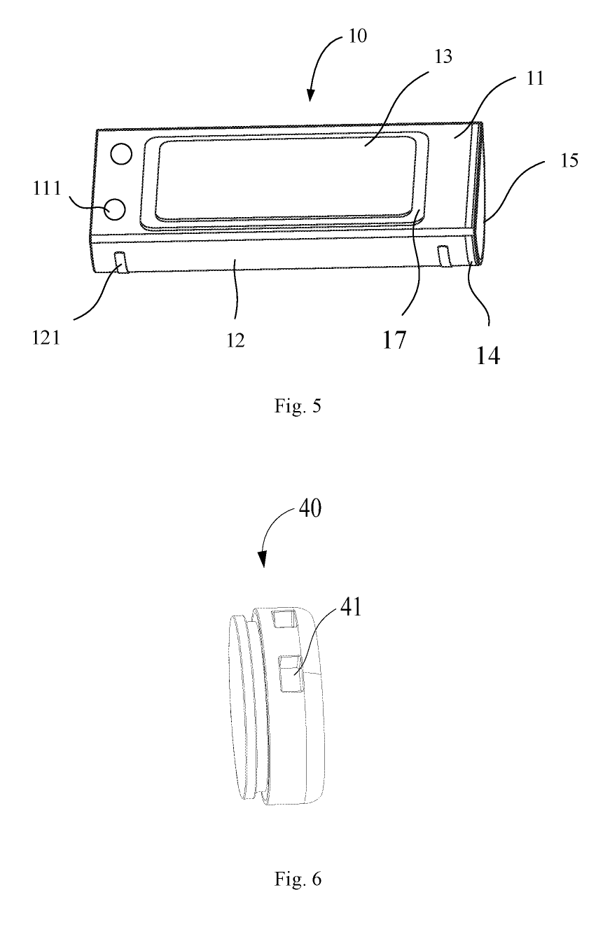

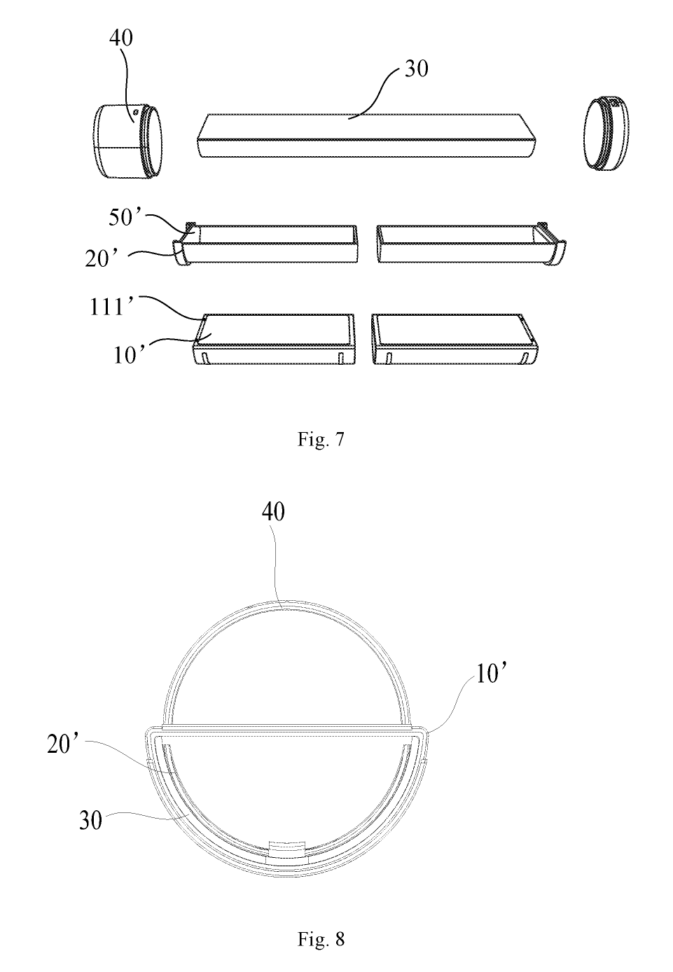

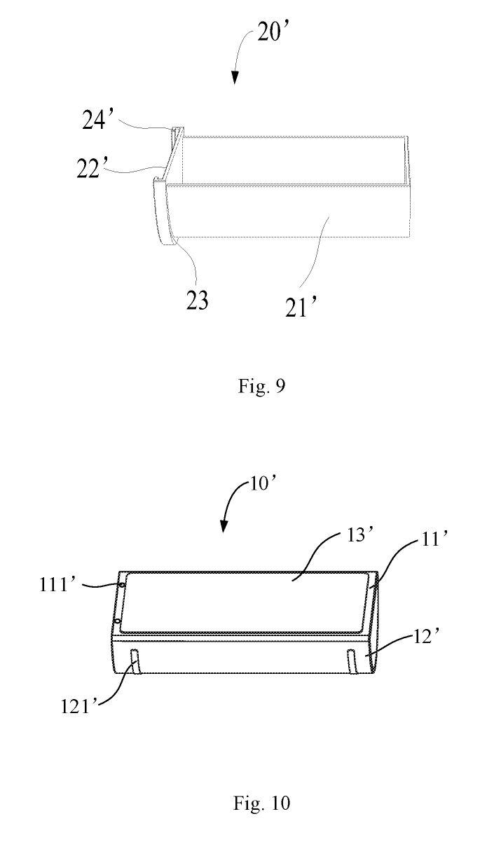

As shown in FIG. 1 to FIG. 10, an embodiment of the present invention provides a supporting bracket for a mobile terminal such as a mobile phone (not shown). The supporting bracket comprises a first bracket body 10 (10′) provided with a bearing surface 11 (11′) for supporting the mobile terminal and a supporting surface 12 (12′) located below the bearing surface 11 (11′), and the bearing surface 11 (11′) is connected with the opposite ends of the supporting surface 12 (12′). In seccific asslications, the supporting bracket is placed on a platform through the support surface 12 (12′) sit on the platform, one end of the mobile terminal is supported on the platform, and the part of the mobile terminal away from the platform leaned against the bearing surface 11 (11′). Thus, the angle formed between the platform and the mobile terminal leaned on the bearing surface 11 (11′) can be changed by moving the first bracket body 10 (10′) toward or away from the mobile terminal and/or rolling the supporting surface 12 (12′) on the platform so as to adapt to the needs of different angles of the mobile terminal in use. Preferably, the supporting surface 12 (12′) is curved such as C-shaped or U-shaped so as to reduce the friction formed between the supporting surface 12 (12′) and the platform.

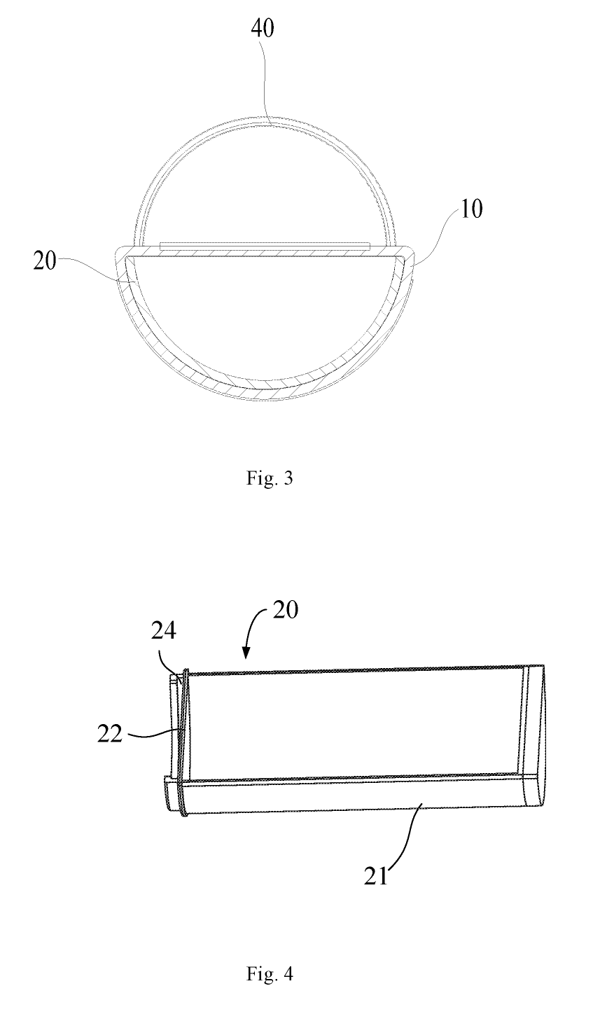

In this embodiment, the first bracket body 10 (10′) is provided with a holding cavity formed between the supporting surface 12 (12′) and the bearing surface 11 (11′), and the bearing surface 11 (11′) is connected with oppsite ends of the supporting suface 12 (12′) in the width direction of the first bracket body 10 (10′) so as to form a D-shaped cross section as shown in FIG. 3. The supporting bracket further includes a second bracket body 20 (20′) comprising a curved plate 21 (21′) and two end plates 22 (22′) respectively disposed at opposite ends of the curved plate 21 (21′). The curved plate 21 (21′) has a C-shaped or U-shaped cross section so that a C-shaped or U-shaped receiving space is formed between the two end plates 22 (22′) and the curved plate 21 (21′). The receiving space can be used as a storage bin for storing articles such as stationery or ornament. The curved plate 21 (21′) is slidably installed in the holding cavity. The length of the second bracket body 20 (20′) is larger than or equal to the length of the first bracket body 10 (10′). At least one of the two side plates 22 (22′) extend outside the holding cavity for facilitating drawing the second bracket body 20 (20′) out from the inside of the first bracket body 10 (10′).

In this embodiment, both the number of the first bracket body 10 (10′) and the number of the second bracket body 20 (20′) are two, the two first bracket bodies 10 (10′) are connected to each other at the connecting ends and the free ends of the two first bracket bodies 10 (10′) extend in directions away from the connecting ends. One end of each of the second bracket bodies 20 (20′) is inserted into the free end of a corresponding first bracket body 10 (10′) so that the two second bracket bodies 20 (20′) are fixed to the two first bracket bodies 10 (10′).

As shown in FIG. 2 to FIG. 6, in this embodiment, each of the connecting ends of the two first bracket bodies 10 (10′) is provided with a baffle 14, and the supporting surface 12, the bearing surface 11 and the baffle 14 are connected with one another to form the holding cavity. The two baffles 14 are respectively provided with a first magnetic member 15 and a second magnetic member 16attractive to the first magnetic member 15. At least one of the first magnetic member 15 and the second magnetic member 16 is made of permanent magnet and the other one of the first magnetic member 15 and the second magnetic member 16 may be made of permanent magnet or magnet conductive material. The two first bracket bodies 10 are fixed to each other by the attractive force of the first magnetic member 15 and the second magnetic member 16. Inner ends of the two second bracket bodies 20 are respectively inserted into the free ends of the two first bracket bodies 10, outer ends of the two second bracket bodies 20 respectively extend outside the two first bracket bodies 10, so that the second bracket bodies 20 are slidably connected with the first bracket bodies 10 and the supporting bracket is retractable so as to adapt to the mobile terminals of different sizes.

The bearing surface 11 (11′) is provided with an anti-skid mat 13(13′) for preventing the mobile terminals from sliding relative to the bearing surface 11 (11′). As a preferred embodiment, the bearing surface 11 (11′) is further provided with a third magnetic member 17 and a fourth magnetic member 18 attractive to the third magnetic member. At least one of the third magnetic member 17 and the fourth magnetic member 18 is made of permanent magnet and the other one of the third magnetic member 17 and the fourth magnetic member 18 may be made of permanent magnet or magnet conductive material. The third magnetic member 17 and the fourth magnetic member 18 are both located between the bearing surface 11 (11′) and the anti-skid mat 13 (13′). The two first bracket bodies 10 (10′) are stacked together so that the supporting bracket is convinient for carrying when in not use.

As a preferred embodiment, the bearing surface 11 (11′) are provided with through holes 111 (111′). Each of the two second bracket bodies 20 (20′) is installed with a heat-dissipated device 50 (50′) for dissipating heat generated by the mobile terminal through the web-shaped through holes 111 (111′). Preferably, the heat-dissipated device 50 (50′) is a fan, and the airflow generated by the fan can take heat away from the mobile terminal and dissipate it to the environment through the through holes 111 (111′).

As a preferred embodiment, the supporting bracket further includes two insertion members 40. Each of the two side plates 22 (22′) of the second bracket body 20(20′) is provided with a curved groove 24 (24′) so as to facilitate drawing the second bracket body 20 (20′) out from the opposite sides of the supporting bracket conveniently. The two insertion members 40 are respectively inserted into the two curved grooves 24 (24′), and the insertion member 40 can be used as a limiting plate to prevent the mobile terminal located on the first bracket body 10 (10′) from moving left and right. The insertion member 40 is provided with containg grooves 41 which can be used for inserting flowers, placing stationery or installing a USB interface for connecting with a mobile terminal.

As a preferred embodiment, a plurality of arc-shaped ribs 121 are arranged at the bottom of the supporting surface 12 (12′), and the arc-shaped ribs 121 are arranged along the length direction of the supporting surface 12 and each rib 121 extends in the width direction of the supporting surface 12 (12′) so as to reduce the friction formed between the supporting bracket and the platform.

The first bracket body 10 (10′) of an embodiment of the present invention is provided with a bearing surface 11 (11′) for supporting the mobile teminal and a supporting surface 12 (12′) located below the bearing surface 11 (11′) for supporting and changing the angle of the mobile terminal on the bearing surface 11 (11′) relative to the platform. The supporting surface 12 (12′) is preferably a curved surface. The angle formed between the platform on which the supporting bracket is placed and the mobile terminal leaned on the bearing surface 11 (11′) can be changed by moving the supporting surface 12 (12′) back and forth relative to the user and/or rolling the supporting surface 12 (12′) on the platform. Besides, the two second bracket bodies 20 (20′) can be withdrawn along the opposite direction of the supporting bracket from the inside of the first bracket body 10 (10′) and the supporting bracket is thus retractable so as to fit the mobile terminal of different sizes. The supporting bracket can be dismantled/disassembled without tools and easy for carrying. Therefore, the supporting bracket is simple in structure, convenient to carry and easy to adjust the angle formed between the platform with the supporting bracket placed thereon and the mobile terminal leaned on the bearing surface, and easy to be widely used.

The difference between the supporting bracket in this embodiment and the supporting bracket in the first embodiment is mainly in the connection manner of the two first bracket bodies 10 (10′) which is specifically as follows: as shown in FIG. 2 to FIG. 6, the two first bracket body 10 are connected to each other by a magnetic attractive force in the first embodiment. And the two first bracket bodies 10′ are connected to each other by a third frame 30 in the second embodiment. Specifically, in the second embodiment, the supporting bracket further comprises a third bracket body 30 which is hollow, and opposite ends of the third body 30 are respectively disposed in the two first bracket bodies 10′, and one end of each of the second bracket bodies 20′ are slidably disposed in a corresponding third bracket body 30 so as to connect the two first bracket bodies 10′, the two second bracket bodies 20′ and the third bracket body 30.

As a preferred embodiment, the second bracket body 20′ is provided with a limiting portion 23 for limiting the insertion depth of the second bracket body 20′ inserting into the third bracket body 30, and the third bracket body 30 is mounted between the two limiting portions 23 so as to prevent the second bracket body 20′ from one side of the third bracket body 30 dircetly through the third bracket body 30 and moving into the other side of the third bracket body 30, therfore the limiting portion 23 cannot fix the second bracket body 20′.

Except for the difference described above, other structures of the supporting bracket in this embodiment may refer to the optimized design of the first embodiment and will not be described in detail herein.

A person skilled in the art may make various other corresponding changes and deformations based on the described technical solutions and concepts. And all such changes and deformations shall also fall within the scope of the present invention.

What is claimed is:

1. A supporting bracket for supporting a mobile terminal on a platform, comprising:
a first bracket body provided with a bearing surface for supporting the mobile terminal and a supporting surface located below the bearing surface and configured for siting on the platform in order to support the bearing surface and change an angle formed between the platform with the supporting bracket placed thereon and the mobile terminal leaned on the bearing surface;
wherein the supporting surface is a curved surface, and the bearing surface is connected with opposite ends of the supporting surface.

2. The supporting bracket of claim 1, wherein the first bracket body is provided with a holding cavity formed between the supporting surface and the bearing surface, the supporting bracket further includes a second bracket body comprising a curved plate and two end plates respectively disposed on opposite ends of the curved plate, and the curved plate is slidably installed in the holding cavity and at least one of the two end plates extends outside the holding cavity.

3. The supporting bracket of claim 2, wherein the supporting bracket comprises a pair of the first bracket bodies and a pair of the second bracket bodies, each of the first bracket bodies has a connecting end and a free end opposite to the connecting end, the connecting ends are connected to each other, and inner ends of the second bracket bodies are respectively inserted into the free ends of the first bracket bodies.

4. The supporting bracket of claim 3, wherein each of the connecting ends of the first bracket bodies is provided with a baffle, and the supporting surface, the bearing surface and the baffle are connected to one another to form the holding cavity, the baffles of the pair of the first bracket bodies are respectively provided with a first magnetic member and a second magnetic member attractive to the first magnetic member, wherein at least one of the first magnetic member and the second magnetic member is made of permanent magnet; the first bracket bodies are connected to each other by a magnetic attractive force formed between the first magnetic member and the second magnetic member; outer ends of the second bracket bodies respectively extend outside the first bracket bodies.

5. The supporting bracket of claim 3, wherein the supporting bracket further comprises a third bracket body which is hollow, opposite ends of the third body are respectively disposed in the pair of the first bracket bodies, and the inner ends of the pair of the second bracket bodies are slidably disposed in the third body respectively.

6. The supporting bracket of claim 5, wherein the second bracket body is provided with a limiting portion for limiting the insertion depth of the second bracket body inserting into the third bracket body, and the third bracket body is mounted between the two limiting portions.

7. The supporting bracket of claim 3, wherein the bearing surface is provided with an anti-skid mat.

8. The supporting bracket of claim 7, wherein the bearing surface is further provided with a third magnetic member and a fourth magnetic member attractive to the third magnetic member, wherein at least one of the third magnetic member and the fourth magnetic member is made of permanent magnet, and the third magnetic member and the fourth magnetic member are both located between the bearing surface and the anti-skid mat.

9. The supporting bracket of claim 2, wherein the supporting bracket further includes two insertion members, each of the end plates of the second bracket body is provided with a curved groove, and the two insertion members are respectively inserted into the two curved grooves.

10. The supporting bracket of claim 9, wherein the insertion member is provided with containg grooves.

11. The supporting bracket of claim 1, wherein a plurality of arc-shaped ribs are arranged at the bottom of the supporting surface.

12. The supporting bracket of claim 11, wherein the arc-shaped ribs are arranged along a length direction of the supporting surface and each rib extends along a width direction of the supporting surface.

13. The supporting bracket of claim 1, wherein the bearing surface are provided with through holes.

14. The supporting bracket of claim 13, wherein the through holes are arranged in a web shape.

15. The supporting bracket of claim 3, wherein each of the two second bracket bodies is installed with a heat-dissipated device.

16. The supporting bracket of claim 15, wherein the heat-dissipated device is a fan.

17. A supporting bracket for supporting a mobile terminal on a platform, comprising:
a first bracket body provided with a bearing surface for supporting the mobile terminal and a supporting surface located below the bearing surface and configured for siting on the platform; and
a second bracket body comprising two end plates and a receiving space formed between the two end plates;
wherein a holding cavity is formed between the supporting surface and the bearing surface of the first bracket body, and the second bracket body is slidably mounted in the holding cavity of the first bracket body with at least one of the two end plates extending outside the holding cavity to expose the receiving space from the first bracket body.

18. The supporting bracket of claim 17, wherein the supporting bracket comprises a pair of the first bracket bodies and a pair of the second bracket bodies, each of the first bracket bodies has a connecting end and a free end opposite to the connecting end, the connecting ends of the first bracket bodies are connected to each other, and inner ends of the second bracket bodies are respectively inserted into the free ends of the first bracket bodies.

19. The supporting bracket of claim 18, wherein the connecting ends of the pair of the first bracket bodies are respectively provided with a first magnetic member and a second magnetic member attractive to the first magnetic member.
